(19) United States
(12) Patent Application Publication
(10) Pub. No.: US 2022/0263293 A1
(43) Pub. Date: Aug. 18, 2022

(54) SEMICONDUCTOR LASER AND MATERIAL MACHINING METHOD USING A SEMICONDUCTOR LASER

(71) Applicant: OSRAM Opto Semiconductors GmbH, Regensburg (DE)

(72) Inventors: Muhammad Ali, Upper Cambourne (GB); Harald König, Bernhardswald (DE); Bernhard Stojetz, Wiesent (DE); Alfred Lell, Maxhütte-Haidhof (DE)

(21) Appl. No.: 17/594,399

(22) PCT Filed: Apr. 8, 2020
(86) PCT No.: PCT/EP2020/060014

§ 371 Date: Oct. 14, 2021

(30) Foreign Application Priority Data
Apr. 17, 2019 (DE) 10 2019 110 189.1

(51) Int. Cl. H01S 5/40; H01S 5/024; H01S 5/30; H01S 5/02315

(52) U.S. Cl. CPC H01S 5/4025; H01S 5/02315; H01S 5/3013; H01S 5/02423

(57) ABSTRACT

In one embodiment, the semiconductor laser comprises a carrier and one or more laser bars. The at least one laser bar comprises at least three individual lasers arranged parallel to each other. A deflection optic is arranged downstream of the individual lasers in common. The at least one laser bar and the associated deflection optic are mounted on the carrier and comprise a distance from one another of at most 4 mm.

### CROSS-REFERENCE TO RELATED APPLICATIONS

This patent application is a national stage entry from International Application No. PCT/EP2020/060014, filed on Apr. 8, 2020, published as International Publication No. WO 2020/212221 A1 on Oct. 22, 2020, and claims priority under 35 U.S.C. § 119 from German patent application 10 2019 110 189.1, filed Apr. 17, 2019, the entire contents of all of which are incorporated by reference herein.

### FIELD

A semiconductor laser is specified. In addition, a material processing method using a semiconductor laser is specified.

### BACKGROUND

The documents US 2008/0212191 A1 and US 2012/0039072 A1 refer to assemblies of semiconductor lasers.

An object to be solved is to specify a semiconductor laser with which materials that are highly reflective in the infrared such as copper can be efficiently processed.

This object is solved inter alia by a semiconductor laser with the features of claim 1. Preferred further developments are the subject of the remaining claims.

### SUMMARY

According to at least one embodiment, the semiconductor laser is configured to emit a laser radiation. The laser radiation is coherent radiation. Preferably, the laser radiation is a pulsed radiation. In the same way, the semiconductor laser can also be configured for continuous wave operation, cw for short.

A wavelength of maximum intensity of the laser radiation emitted during operation is preferably at least 390 nm or 400 nm and/or at most 475 nm or 460 nm. Alternatively, it is possible that the wavelength of maximum intensity lies in another spectral range, in particular in the near-infrared spectral range, for example at least 900 nm and/or at most 1200 nm.

According to at least one embodiment, the semiconductor laser comprises a carrier. The carrier may be the component mechanically supporting and stabilizing the semiconductor laser. Preferably, the carrier comprises a high thermal conductivity. For example, the carrier comprises a metal or comprises a metal as an essential component, in particular copper or a copper alloy.

According to at least one embodiment, the semiconductor laser comprises one or more laser bars. The at least one laser bar comprises at least two or at least three or at least four individual lasers. Alternatively or additionally, the number of individual lasers per laser bar is at most 200 or 100 or 30 or 15. The individual lasers are preferably electrically operated in parallel and may be electrically connected in parallel. Alternatively, the individual lasers are electrically connected in series in the laser bar.

Preferably, the individual lasers are operable only when taken together. Alternatively, the individual lasers or groups of individual lasers may be electrically independently operable.

According to at least one embodiment, the individual lasers are oriented parallel or approximately parallel to each other within the respective laser bar. That is, the individual lasers comprise the same or approximately the same emission direction. For example, resonators of the individual lasers are oriented parallel to each other and/or lie in a common plane. Approximately, related to an angle, means here and in the following in particular a tolerance of at most 5° or 1°.

A semiconductor layer sequence and/or a growth substrate of the semiconductor layer sequence for the laser bar preferably extend continuously and uninterruptedly over the entire laser bar, so that all individual lasers are fabricated from the same semiconductor layer sequence. For example, the individual lasers each comprise a ridge waveguide, or ridge.

According to at least one embodiment, the semiconductor laser comprises one or more deflection optics. The at least one deflection optic is arranged downstream of the individual lasers of the laser bar in common. In the case of a single laser bar, the deflection optic is thus common downstream of all the individual lasers. If there are several laser bars, there can be a separate deflection optic for each laser bar or for groups of laser bars, which is downstream of all the individual lasers concerned in common. Furthermore, it is possible for a single deflection optic to be downstream of all the individual lasers of all the laser bars.

According to at least one embodiment, the at least one laser bar and the at least one deflection optic are mounted on the carrier. The at least one laser bar and/or the at least one deflection optic may be mounted directly to the carrier or intermediate components such as intermediate carriers, also referred to as submounts, may be present. That is, the carrier preferably serves as a common, cohesive mounting platform for all laser bars and for all deflection optics.

According to at least one embodiment, the laser bar and associated deflection optic are mounted close together on the carrier. A distance between the laser bar and the associated deflection optic is preferably at most 6 mm or 2 mm or 1 mm or 0.7 mm. Alternatively or additionally, this distance is at least 0.1 mm or 0.3 mm or 0.5 mm.

By taking several individual lasers together in a laser bar and by placing the at least one laser bar close to the associated deflection optic, a beam composed of individual laser beams of the individual lasers can be obtained which comprises a relatively small diameter. This simplifies downstream guiding and focusing of the total laser radiation emitted by the semiconductor laser.

In at least one embodiment, the semiconductor laser comprises a carrier and one or more laser bars. The at least one laser bar comprises at least three individual lasers arranged in parallel. At least one deflection optic is arranged downstream of the individual lasers of the laser bar in common. The at least one laser bar and the associated deflection optic are mounted on the carrier and comprise a distance from each other of at most 4 mm.

Increasingly, semiconductor laser light sources are penetrating application areas that were previously covered by other light sources or other laser systems. In particular, the increase in efficiency of semiconductor lasers based on the InGaN material system, which emit in the visible spectral range, offers new application potential, for example in projection applications, in lighting applications and/or in materials processing.

An important aspect for the high potential of visible laser diodes in material processing is the significantly higher absorption of materials such as copper or gold in the blue spectral range, compared to the near-infrared radiation used as standard for material processing. This has the particular consequence that, for example, the material copper, which is significant for electromobility, can be welded and/or cut without spattering with blue high-power radiation sources. This cannot be achieved with conventional infrared-based light sources, or only at great expense. Therefore, semiconductor lasers described here can enable a key process for leakage-free and/or low-leakage electric drives.

With the semiconductor laser described here, it is possible to provide light sources emitting especially in the blue spectral range with high optical output powers in the region of several 10 W, preferably 100 W to several kW.

Commercially available high-power lasers in the near-infrared spectral range are currently available, which can achieve so-called wall plug efficiencies of about 70%. The wall plug efficiency specifies the quotient of supplied electrical power and emitted optical power. However, the low material absorption of highly reflective metals such as copper or gold means that the required laser power in the near-infrared spectral range is very high, limiting the material thickness that can be processed and, for example, the welding speed or cutting speed. In addition, uniformity and spatter-free operation are severely limited when using near-infrared radiation to process copper and/or gold.

In contrast, currently commercially available laser systems, especially in the blue spectral range, are based on the assembly of individual emitters in a common housing. On the one hand, this drastically limits the optical performance and, in particular, the power density; on the other hand, a high-power light source based on individual emitter assembly is costly to manufacture and prone to defects.

In the semiconductor laser described here, very high optical output powers are made possible by coupling InGaN-based laser bars together with the aid of optical elements. The individual laser bars can, for example, be coupled into a fiber via deflection prisms. Preferably, several laser bars are arranged in a staircase manner on top of each other and imaged via the same deflection prism.

Optionally, a collimating lens can be placed in front of each laser bar or in front of some laser bars, in particular a so-called Fast Axis Collimating Lens, FAC for short. Fast Axis is the term used to describe the direction in which there is rapid beam expansion and high divergence. The so-called Fast Axis is oriented in particular parallel to a growth direction of the semiconductor layer sequence of the associated laser bar.

Optionally, optics such as a lens can be provided in front of a coupling fiber into which the laser radiation of the semiconductor laser is coupled. Furthermore, optional optical shapes such as parabolic mirrors may be integrated into the deflection prism. Furthermore, it is possible for an optical fiber to include converter particles with a luminescent substance in its fiber core and/or cladding, allowing the fiber itself to be luminescent. Furthermore, it is optionally possible that converter particles are incorporated along the fiber in a concentration gradient or with a constant concentration, specifically to compensate for decreasing laser excitation energy.

It is also possible for the semiconductor laser described here to emit in the near-infrared spectral range and, in particular, to be operated in pulsed mode. This allows lidar applications and distance measurements to be addressed, for example.

Thus, with the semiconductor laser described here, a luminous spot with a very high luminance can be realized, accompanied by new possibilities in material processing with metals that are highly reflective in the infrared, such as copper or copper compounds. This can significantly increase the speed of material processing, especially during cutting and/or welding. In addition, spatter-free material processing is possible, which is a basis for current-free or low-leakage electric drives.

In addition, such light sources, optionally in combination with fiber coupling and/or with wavelength converters, are of importance for large-area projection applications, for example for beamers, for backlighting of displays or for light sources such as stadium lighting or in street lamps.

Since the semiconductor laser described here is based on laser bars instead of individual emitters, this results in a considerably reduced assembly effort. The use of a FAC lens also reduces the adjustment effort compared to the required individual mounting of lenses in light sources based on individual laser diodes.

Due to the high absorption, in particular of blue laser radiation, of copper or copper alloys, it is possible to achieve extensive independence of the processing from surface roughness or surface textures.

According to at least one embodiment, the at least one laser bar comprises a semiconductor layer sequence. The semiconductor layer sequence is preferably based on the AlInGaN material system. If multiple laser bars are present, all laser bars may be based on the same material system and configured to emit laser radiation of the same wavelength of maximum intensity. Alternatively, laser bars with different semiconductor layer sequences, also based on different material systems, may be present.

According to at least one embodiment, a fill factor of the laser bar is at least 5% or 8% and/or at most 50% or 35% or 20% or 15% or 12%, in particular between 5% and 50% inclusive or between 5% and 20% inclusive or between 8% and 12% inclusive. The fill factor is a quotient of a laser active area and of a total area of the semiconductor layer sequence. That is, an active area fraction of the semiconductor layer sequence is then comparatively small.

According to at least one embodiment, the laser bars are located on two preferably opposite sides of the deflection optic. The laser bars may also be located on more than two sides of the deflection optic. In particular, laser bars are located on exactly two or on exactly four sides of the deflection optic, in the case of a three-sided pyramid as deflection optic in particular on exactly three sides.

According to at least one embodiment, the laser bars are arranged symmetrically with respect to the associated deflection optic. In particular, viewed in cross-section, a central axis of the deflection optic forms an axis of symmetry between the laser bars.

According to at least one embodiment, the carrier comprises one or more stages. The stages may form one or more stairs arranged, for example, symmetrically with respect to the associated deflection optic. The laser bars are located in two or more planes, preferably parallel or approximately parallel to a base surface of the carrier. Such a staircase with several planes with laser bars can be located at only one or also at two in particular opposite sides of the associated deflection optic.

If the deflection optic narrows in a direction away from the base surface, a space between the laser bars of the planes may increase in a direction away from the base surface if the laser bars are arranged in at least one staircase. That is, with increasing distance from the base surface, a spacing between the deflection optic and the associated laser bar may increase.

Alternatively, it is possible that a distance between the laser bars of the planes along a radiation direction becomes smaller. That is, as the deflection optic becomes narrower, a distance between the laser bars of a plane may decrease. Thus, a distance between the laser bars of different planes and the deflection optic may be kept approximately constant.

The explanations in the two preceding paragraphs apply equally if laser bars are located on different sides of the deflection optic, as well as in the case where a staircase is attached to only one side of the deflection optic. In the latter case, an optical axis of the deflection optic in particular then serves as a reference value for the distance.

According to at least one embodiment, the semiconductor laser comprises a plurality of deflection optics arranged together with associated laser bars along one or along a plurality of, in particular, straight lines on the base surface of the carrier. At least one of these lines comprises once or also several times the following sequence: laser bar-deflection optic-laser bar-laser bar-deflection optic-laser bar. That is, there may be laser bar-deflection optic-laser bar packages of three arranged sequentially along the respective line.

According to at least one embodiment, one or more lenses such as cylindrical lenses optically are arranged downstream of the deflection optic or deflection optics, in particular optically immediately downstream. This applies in particular if the laser bars are present in a two-dimensional, for example matrix-shaped assembly on the carrier.

According to at least one embodiment, the at least one deflection optic comprises a triangular basic shape when viewed in cross-section. Alternatively, the deflection optic is shaped as a trapezoid, in particular as a symmetrical trapezoid, when viewed in cross-section. The cross-section is preferably aligned parallel to a main emission direction of the semiconductor laser. In total, the deflection optic can thus represent a prism, a pyramid or a truncated pyramid. A width of the deflection optic may decrease in a direction away from the carrier.

According to at least one embodiment, the semiconductor laser comprises one or more fast axis collimating lenses. The at least one collimating lens is configured to reduce, in particular eliminate, divergence along a direction comprising a maximum divergence. That is, along the fast axis direction, the laser radiation may comprise no divergence or only negligible divergence after passing through the collimating lens. The at least one collimating lens is preferably located optically immediately downstream of the associated laser bar.

That is, there is then no further optical element between the laser bar and the associated collimating lens.

According to at least one embodiment, the collimating lens is optically and/or geometrically located between the associated laser bar and the associated deflection optic. That is, the laser radiation passes through the collimating optic before impinging on the deflection optic.

According to at least one embodiment, the at least one collimating lens is directly attached to the associated laser bar. That is, the collimating lens may contact the associated laser bar. Alternatively, there is only a bonding agent such as an adhesive between the collimating lens and the laser bars. In the latter case, a distance between the collimating lens and the laser bars is preferably at most 5 μm or 2 μm.

Preferably, there is exactly one collimating lens per laser bar. The collimating lens may be formed similar to a half-cylinder lens. It is possible for the collimating lens to leave a region immediately adjacent to a laser facet, from which the laser radiation is emitted, exposed. Thus, the collimating lens may simultaneously form an encapsulation for the relevant region of the facet.

According to at least one embodiment, the deflection optic immediately optically follows the at least one associated semiconductor laser. That is, between the deflection optic and the respective laser bar there is no further optically effective component, in particular no collimating lens such as a fast axis collimating lens.

According to at least one embodiment, the deflection optic or one of the deflection optics or all deflection optics is/are configured for beam collimation, in particular in fast axis direction. This means that the deflection optics can act as a beam collimator for the laser radiation in question. Thus, parallel or approximately parallel beam bundles may emanate from the deflection optic.

According to at least one embodiment, the carrier is formed as a housing or is integrated in a housing. For example, the carrier may constitute a bottom plate of a housing or define a cavity in which the laser bars are mounted. Furthermore, it is possible that the carrier represents a housing component, for example a mounting platform in a housing such as a TO housing.

According to at least one embodiment, the semiconductor laser comprises one or more optical waveguides. For example, the at least one optical waveguide is attached to the carrier and/or the housing. Laser radiation generated in operation is partially or predominantly or completely coupled into the associated optical waveguide. In particular, the optical waveguide is a combination of a high refractive index core material and a low refractive index cladding material such that the optical waveguide comprises a totally reflective core region.

According to at least one embodiment, the semiconductor laser comprises one or more luminescent substances. The at least one luminescent substance is preferably an inorganic luminescent substance, for example a garnet luminescent substance such as YAG:Ce. The luminescent substance is preferably provided in the form of luminescent particles, for example with a mean diameter of at least 0.1 μm or 0.5 μm and/or at most 50 μm or 20 μm or 10 μm. The luminescent substance is configured for wavelength conversion of a part or all of the laser radiation generated during operation. In particular, the wavelength conversion is towards a longer wavelength spectral range.

According to at least one embodiment, the luminescent substance is located on and/or in the optical waveguide. Preferably, the luminescent substance is thermally linked to a heat sink so that the luminescent substance can be efficiently deheated.

According to at least one embodiment, the at least one laser bar is bond-wire free contacted. For example, the laser bar is attached to the carrier and/or to a submount using surface mount technology, or SMT for short. Bond-wire-free mounting of the laser bar allows high currents to be realized with short pulse durations.

According to at least one embodiment, the carrier comprises one or more electrical leads. The at least one electrical lead is preferably routed through the carrier. The electrical lead may simultaneously ensure a thermal connection of the laser bar to a cooling unit.

According to at least one embodiment, the carrier and/or the housing comprises one or more cooling channels. The at least one cooling channel is preferably configured to have a cooling liquid flowing therethrough. For example, a heat transport capacity achieved by means of the cooling channels and the cooling liquid is at least 0.1 kW or 0.5 kW or 1 kW. That is, high thermal power losses can be dissipated by means of such cooling channels.

According to at least one embodiment, the semiconductor laser comprises a mean optical output power of at least 0.2 kW or 0.4 kW or 0.8 kW. Alternatively or additionally, the mean optical output power is at most 20 kW or 10 kW or 5 kW. Thus, the semiconductor laser emits high optical output powers, which are required for welding and/or cutting, for example, copper. Alternatively or additionally, the laser radiation emitted by the semiconductor laser can be collimated, for example on a luminous spot with a mean diameter of at most 1 mm or 0.1 mm or 0.02 mm.

Furthermore, a material processing method is specified. The material processing method uses a semiconductor laser as described in connection with one or more of the above embodiments. Features of the semiconductor laser are therefore also disclosed for the material processing method, and vice versa.

In at least one embodiment, the semiconductor laser is used to cut and/or weld copper or a copper alloy. This is preferably done by means of blue laser radiation, for example with a mean optical power of at least 0.2 kW or 0.4 kW or 0.8 kW. For material processing, the beam bundles emitted by the individual lasers of the laser bar or the laser bars are preferably combined within the semiconductor laser by means of the deflection optic and guided, for example, by means of an optical waveguide to the material to be processed and/or focused on the material to be processed with the aid of an optic.

In the following, a semiconductor laser described herein and a material processing method described herein are explained in more detail with reference to the drawing by means of exemplary embodiments. Identical reference signs specify identical elements in the individual figures. However, no references true to scale are shown; rather, individual elements may be shown exaggeratedly large for better understanding.

### BRIEF DESCRIPTION OF THE DRAWINGS

In the figures:

FIGS. 1 to 3 show schematic sectional views of exemplary embodiments of semiconductor lasers described herein;

FIG. 4 shows a schematic top view of an exemplary embodiment of a semiconductor laser described herein;

FIGS. 5 to 7 show schematic sectional views of exemplary embodiments of semiconductor lasers described herein;

FIGS. 8 to 10 show schematic top views of exemplary embodiments of semiconductor lasers described herein;

FIGS. 11 to 17 show schematic sectional views of exemplary embodiments of semiconductor lasers described herein;

FIG. 18 shows a schematic perspective view of an exemplary embodiment of a material processing method described herein,

FIG. 19 shows a schematic representation of the wavelength-dependent absorption of copper and gold, and

FIG. 20 shows a schematic top view of a laser bar for semiconductor lasers described herein.

### DETAILED DESCRIPTION

FIG. 1 illustrates an exemplary embodiment of a semiconductor laser 1. The semiconductor laser 1 comprises a carrier 4, for example a metal plate, in particular made of copper or a copper alloy. The carrier 4 forms a base surface 40.

A laser bar 2 and a deflection optic 3 are attached to the base surface 40. The deflection optic 3 is, for example, prism-shaped and comprises a reflection surface 30 facing the laser bar 2. The reflection surface 30 is provided with a reflective coating, such as a Bragg mirror, and/or has a total reflective effect for a laser radiation L emitted during operation. The deflection optic 3 is, for example, a prism and is shaped like a triangle in cross-section.

The laser radiation L is emitted from the laser bar 2 toward the deflection optic 3, wherein an optical axis of the laser bar 2 is oriented approximately parallel to the base surface 40. The laser radiation L is redirected by the deflection optic 3 in a main emission direction M. The main emission direction M is oriented approximately perpendicular to the base surface 40.

The laser bar 2 comprises several individual lasers, not illustrated in FIG. 1. The individual lasers are preferably arranged side by side in a direction perpendicular to the drawing plane of FIG. 1. For example, the laser bar 2 comprises at least four and/or at most 100 individual lasers. For example, the laser bar 2 is based on the material system AlInGaN, so that the laser bar 2 can be configured for the emission of blue laser radiation L.

Optionally, the laser bar 2 is located on an intermediate carrier 8, also referred to as a submount. It is possible that the laser bar 2 projects beyond the intermediate carrier 8 in a direction towards the deflection optic 3 or is flush with the intermediate carrier 8.

The intermediate carrier 8 is designed, for example, merely as a heat sink or as a heat dissipating component towards the carrier 4. Alternatively, it is possible that the intermediate carrier 8 is further electrically functionalized and comprises, for example, conductor paths or further drive components for the semiconductor laser 1 such as capacitors and/or transistors.

By means of the intermediate carrier 8, it is in particular achievable that the laser bar 2 comprises a sufficient distance to the base surface 40. In particular along a fast axis direction, in FIG. 1 parallel to the main emission direction M, the laser radiation L is emitted from the laser bar 2 with a relatively large divergence. For example, a divergence angle within which 90% or 95% of the laser radiation L is emitted is at least 45° or 70° and/or at most 100° or 80°. Thus, a thickness of the intermediate carrier 8 is approximately equal to a distance between the laser bar 2 and the deflection optic 3, which distance is, for example, approximately 0.5 mm or approximately 1 mm.

An electrical connection of the laser bar 2 is made, for example, via bonding wires 46 and via electrical leads 45, in each case drawn in a highly simplified manner in the figures. For example, at least one bonding wire 46 contacts the intermediate carrier 8 and at least one further bonding wire 46 contacts a side of the laser bar facing away from the carrier 4. Preferably, several bonding wires 46 are present in each case. Electrical contact schemes deviating from this are also possible.

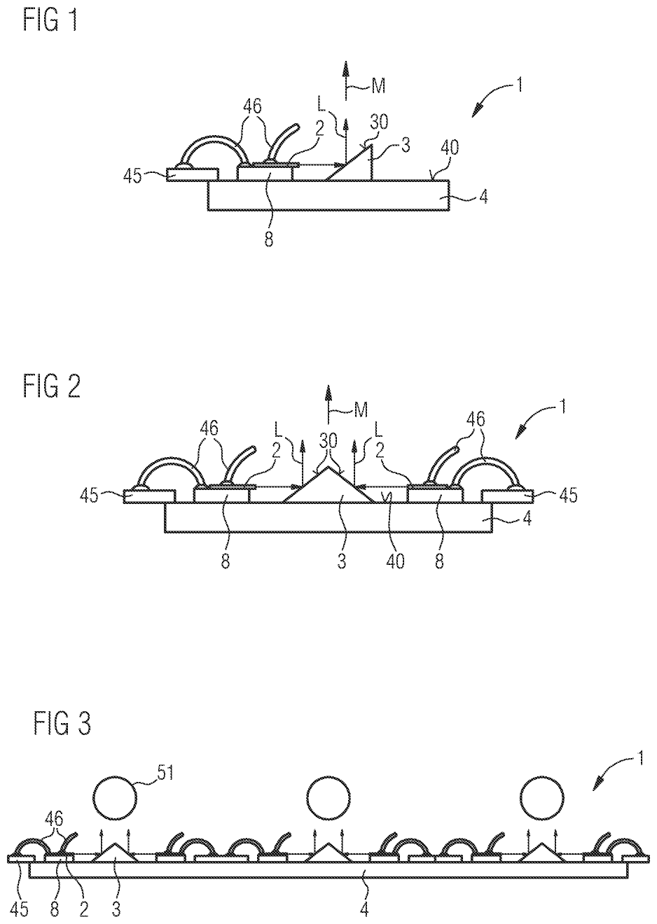

In the exemplary embodiment of FIG. 2, it is illustrated that the laser bars 2 are arranged on both sides of the deflection optic 3, again optionally each on an intermediate carrier 8. The deflection optic 3 thus comprises two reflection surfaces 30. The laser bars 2 are preferably arranged symmetrically with respect to a centerline of the deflection optic 3. Seen in cross-section, the deflection optic 3 is shaped as an isosceles triangle.

In all other respects, the comments on FIG. 1 apply accordingly to FIG. 2, as is also possible for all other exemplary embodiments.

In the exemplary embodiment of FIG. 3 it is illustrated that several laser bars 2 and several deflection optics 3 are arranged successively along a preferably straight line. That is, there may be a linear, one-dimensional assembly.

Optionally, each of the deflection optics 3, or all of the deflection optics 3 taken together, is followed by an optical component. For example, each deflection optic 3 is followed by a cylindrical lens 51. The cylindrical lenses 51 can be used for fast axis collimation. Such lenses 51 may also be present in all other exemplary embodiments. Such cylindrical lenses 51 may be combined with other optical components, not shown.

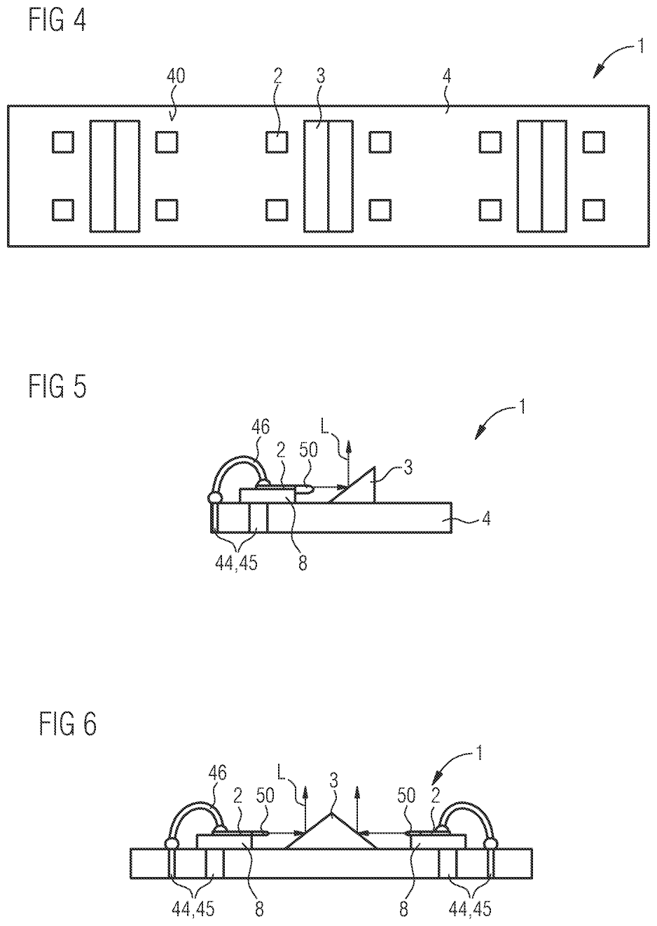

In the exemplary embodiment of FIG. 4, there is a two-dimensional assembly of the laser bars 2, and not only a one-dimensional assembly as drawn in FIG. 3. Thus, along a longitudinal direction of the deflection optics 3, several of the laser bars 2 are arranged in each case. For example, there are 2×2 of the laser bars 2 per deflection optic 3. Instead of connected deflection optics 3, each pair of laser bars 2 can also have its own deflection optic 3. Cylindrical lenses, not drawn in FIG. 4, can be present in FIG. 4 in the same way as in FIG. 3.

In the exemplary embodiment of FIG. 5 it is illustrated that the electrical leads 45 are led through the carrier 4 and represent electrical through-connections 44. The intermediate carrier 8 is mounted on one of these through-connection 44 and serves to supply the laser bar 2 with current. For example, the intermediate carrier 8 is a solid metal block.

Another through-connection 44 is connected to the laser bar 2 via at least one bonding wire 46. Depending on the electrical interconnection, more than two through-connections 44 may be provided in the carrier 4. The through-connections 44 are preferably made of an electrically conductive and thermally conductive material such as copper. Electrical insulations between a material of the through-connections 44 and a remaining material of the, for example, metallic carrier 4 are not drawn.

Optionally, a fast axis collimating lens 50 is preferably located directly on the laser bar 2. The collimating lens 50 preferably extends with a constant shape along the entire laser bar 2, i.e., in a direction perpendicular to the drawing plane of FIG. 5.

The collimating lens 50 may alternatively or additionally be in contact with the deflection optic 3 or directly attached to the deflection optic 3. Furthermore, the collimating lens 50 can be arranged at a distance from both the laser bar 2 and the deflection optic 3.

In the exemplary embodiment of FIG. 6, an assembly of the laser bars 2 is shown as illustrated in connection with FIG. 2. Electrical contact is made in the same way as in FIG. 5. Such electrical contact can also be used in the other exemplary embodiments. Seen in cross-section, the deflection optic 3 is designed as a symmetrical trapezoid.

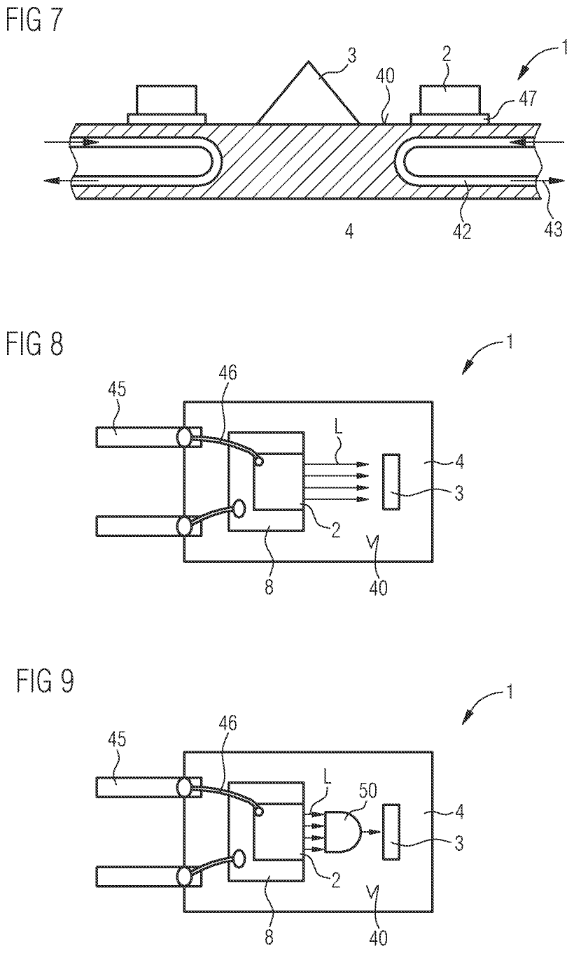

In the exemplary embodiment of FIG. 7, it is shown that the laser bars 2 are mounted on electrical contact regions 7. In this case, the contacting is preferably bond-wire-free. The laser bars 2 are thus SMT components. Optionally, additional intermediate carriers may be present, not drawn. In all exemplary embodiments, the laser bars 2 may also be SMT components.

Furthermore, it is illustrated in FIG. 7 that the carrier 4 may comprise a cooling device. The cooling device is formed, for example, by cooling channels 42 through which a cooling liquid 43 flows during operation. This allows thermal waste heat to be efficiently dissipated from the semiconductor laser 1 even in the kilowatt region.

FIG. 8 schematically illustrates that the semiconductor laser 1 may be designed as a TO-220 package within which the laser bar 2 and the deflection optic 3 are mounted. The electrical leads 45 are configured, for example, as pins that can be inserted into or through an external circuit board, not drawn. An electrical connection of the laser bar 2 as well as the optional intermediate carrier 8 is made, for example, via the bonding wires 46.

In FIG. 8, the deflection optic 3 follows the laser bar 2 optically directly. In contrast, the collimating lens 50 is present in FIG. 9. In all other respects, the exemplary embodiment of FIG. 9 corresponds to the exemplary embodiment of FIG. 8. As an alternative to fast axis collimating lenses mounted directly on the laser bar 2, collimating lenses 50 may also be mounted at a distance from the associated semiconductor laser bar 2, as illustrated in FIG. 9. This is also possible in all other exemplary embodiments.

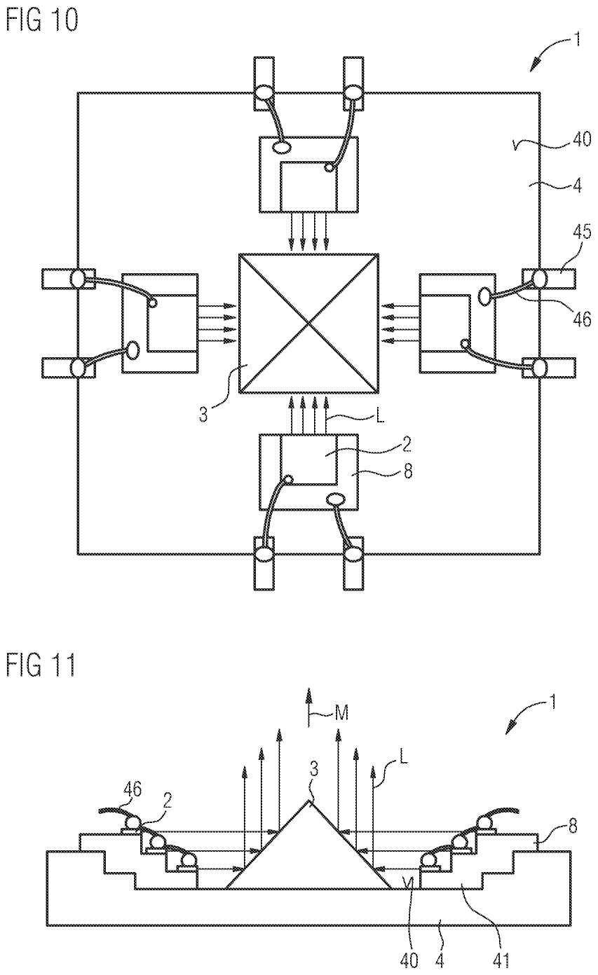

According to FIG. 10, the deflection optic 3 is formed as a pyramid. This means that four different laser bars 2 can be attached to the four sides of the deflection optic 3.

In order to reflect a high proportion of the emitted laser radiation L at the deflection optic 3, a length of the laser bars 2 is preferably smaller than a base length of the deflection optic 3. With such a deflection optic 3, a relatively large area can be illuminated. Thus, such a semiconductor laser 1 can serve, for example, to illuminate a luminescent substance, not drawn. Optionally, fast axis collimating lenses can be provided.

In the exemplary embodiment of FIG. 11, it can be seen that the intermediate carriers 8 are attached to the base surface 40 in a staircase-like manner in several stages 41. In a direction away from the base surface 40 and thus along the main emission direction M, the stairs run away from the deflection optic 3, which narrows in the direction away from the base surface 40.

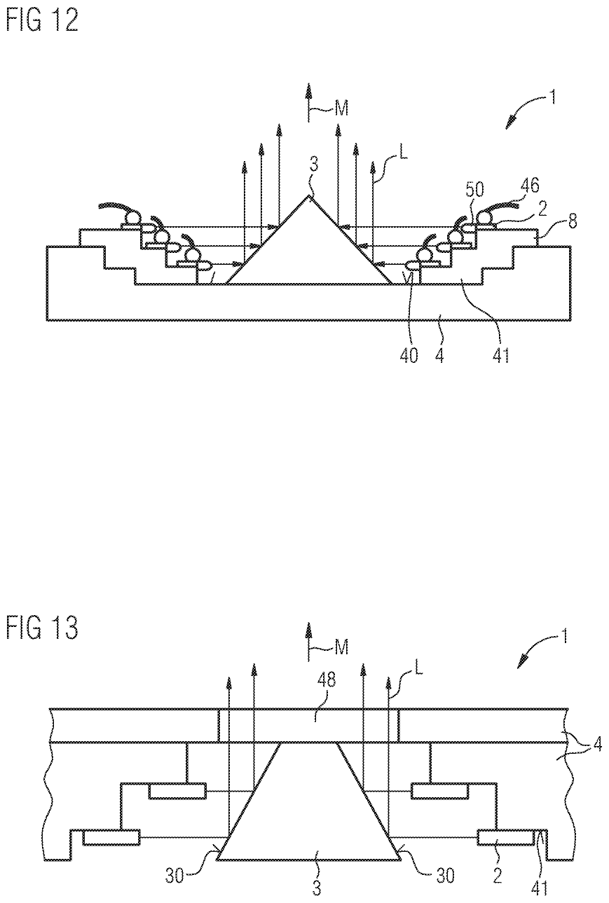

The exemplary embodiment of FIG. 12 corresponds to that of FIG. 11, wherein, however, the collimating lenses 50 are additionally present.

In the assemblies of FIGS. 11 and 12, a distance between the laser bars 2 and the deflection optic 3 increases along the main emission direction M. This is compensated in FIG. 13 by the fact that the stages comprise the same course or a similar course to the reflection surfaces 30 of the deflection optic 3. Thus, an approximately constant distance of the laser bars 2 to the reflection surfaces 30 can be achieved across the stages.

Optionally, the carrier 4 comprises a window 48 to which the deflection optic 3 can be attached and/or through which the laser radiation L can leave the semiconductor laser 1. A corresponding stage arrangement may also be present in the other exemplary embodiments with stairs in the same manner.

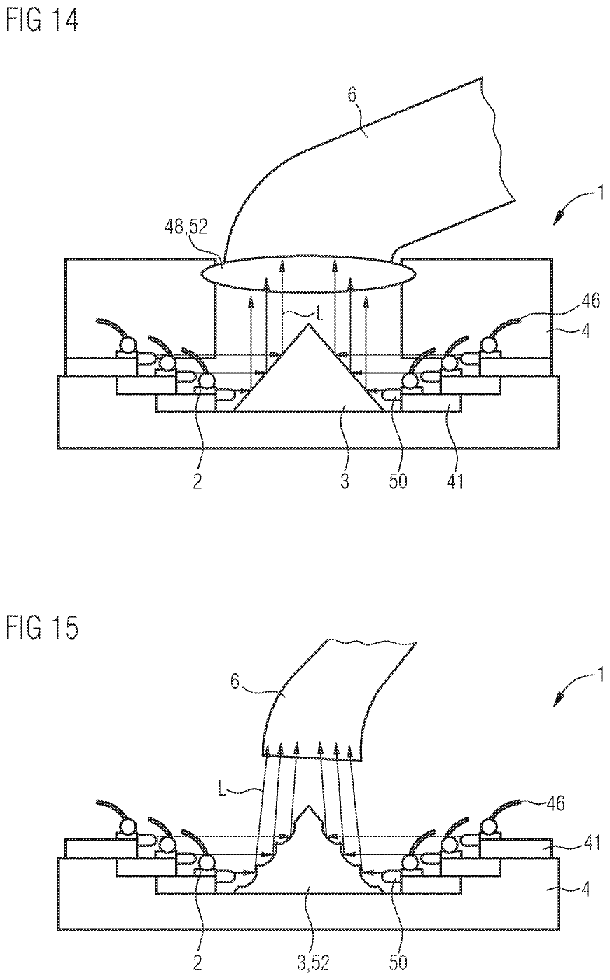

In the exemplary embodiment of FIG. 14, it is illustrated that the carrier 4 with the stages 41 and the optional collimating lenses 50 forms a housing in which the deflection optic 3 is also located. Optionally, the window 48 is designed as an optic 52, for example as a converging lens. As in all other exemplary embodiments, the deflection optic 3 as well as the laser bar 2 are thus preferably hermetically housed.

Optionally, an optical waveguide 6 is located at the window 48, in which the partial radiation of the laser radiation L of the individual laser bars 2 can be combined and mixed with each other and transported to a desired location without requiring significant free beam distances.

In particular, in assemblies of laser bars 2 as shown in FIGS. 3 and 4, there may be multiple optical waveguides.

In FIG. 15 it is illustrated that the deflection optic 3, preferably alternatively to the collimating lenses 50 nevertheless illustrated in FIG. 15, comprises optical effective facets. For example, individual regions for the individual laser bars 2 are designed as concave mirrors for collimating and selectively directing the laser radiation L into specific solid angle regions. Seen in cross-section, the deflection optic 3 is still approximately triangular in shape.

Curvatures of the individual facet areas can be adjusted to the distance of the associated laser bar 2, so that especially a fast axis widening can be compensated uniformly for the laser bars 2 of different planes. The same applies to all other exemplary embodiments. By means of such facets of the deflection optic 3, an efficient coupling into the optical waveguide 6 can be realized.

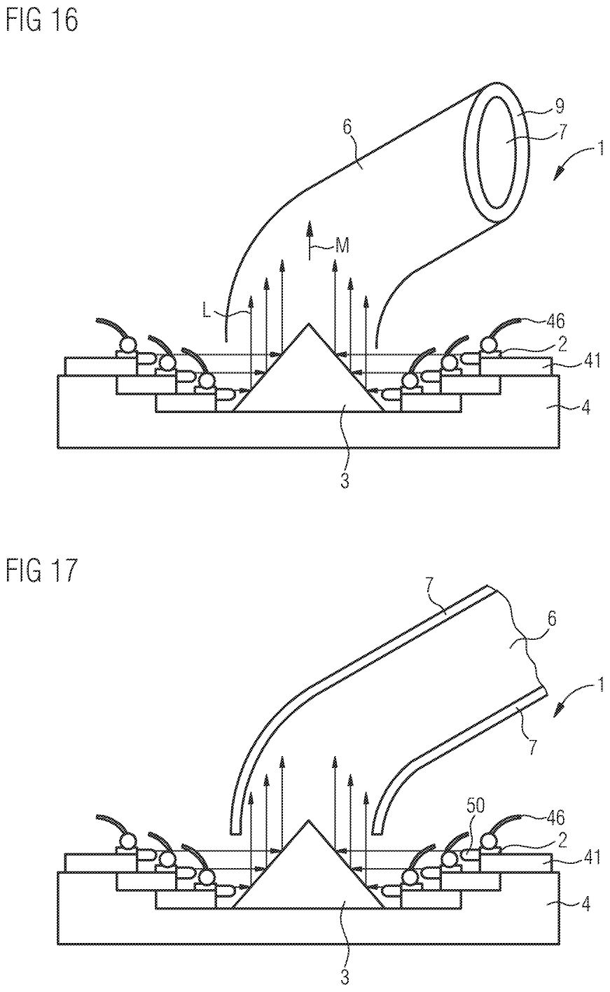

In the exemplary embodiment of FIG. 16, it is illustrated that a luminescent substance 7 can be attached to one end of the optical waveguide 6. A heat sink 9 is preferably attached around the luminescent substance 7 for efficient cooling, in particular made of a material with good thermal conductivity such as silicon carbide, sapphire, aluminum oxide or aluminum nitride, DLC (diamond like carbon). Preferably, an optically effective coating is present on the luminescent substance 7 on a side optically facing the deflection optic 3. Such a coating is preferably highly reflective for the converted radiation and/or comprises a high transmittance for the laser radiation L. Hereby an efficient radiation in a certain direction and an efficient conversion of the laser radiation L are possible.

In the exemplary embodiment of FIG. 17 it is illustrated that the luminescent substance 7 is attached to an inner wall of the optical waveguide 6. Preferably, there is a heat sink around the outside of the layer with the luminescent substance 7, not drawn. Alternatively, the luminescent substance 7 may be embedded in the optical waveguide 6, for example with a concentration gradient, to counteract decreasing laser intensity along the optical waveguide 6. This makes it possible to realize an optical waveguide 6 that emits light uniformly along its cladding surface.

By means of the luminescent substance L, incoherent white light or colored light can be generated from blue laser radiation L, for example.

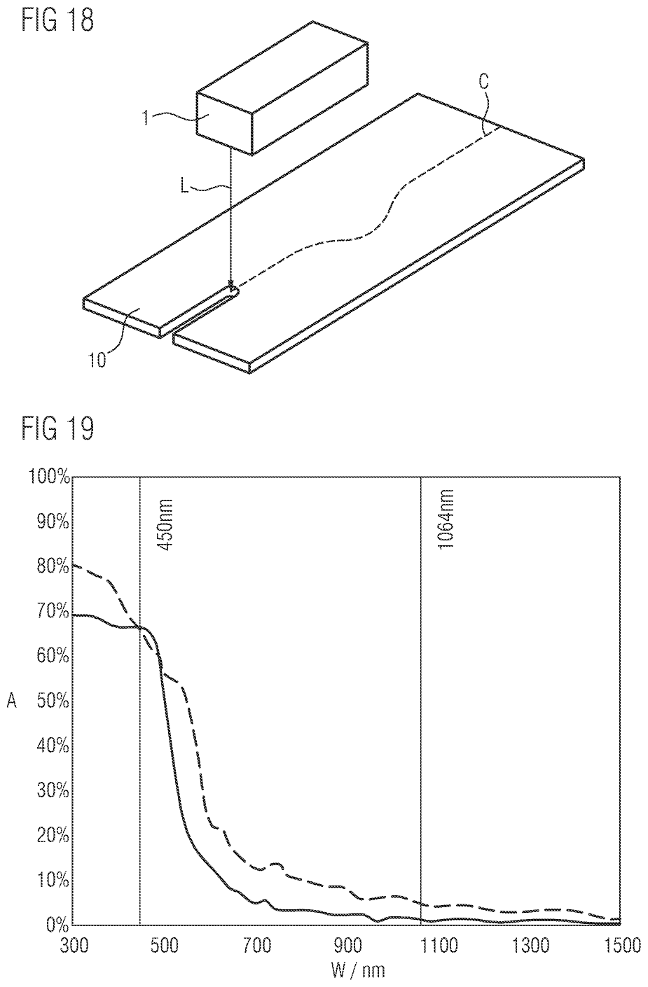

FIG. 18 schematically shows a material processing method. The semiconductor laser 1 emits the laser radiation L, preferably blue light. A workpiece 10 is cut along a cutting line C. Due to the high laser power of the semiconductor laser 1, high cutting speeds can be achieved. As an alternative to cutting, welding can be performed.

As an alternative to material processing, semiconductor lasers 1 described here, especially with emission in the near-infrared spectral range, can also be used for applications such as distance determination and/or lidar.

FIG. 19 illustrates a curve of an absorption A in percent versus a wavelength W in nm. It can be seen that the absorption in the blue spectral range around 450 nm is considerably greater for copper and gold than in the near-infrared spectral range at a typical processing wavelength of 1064 nm. This means that materials such as copper or gold can be processed much more efficiently and, in particular, without spattering with blue light than with infrared radiation.

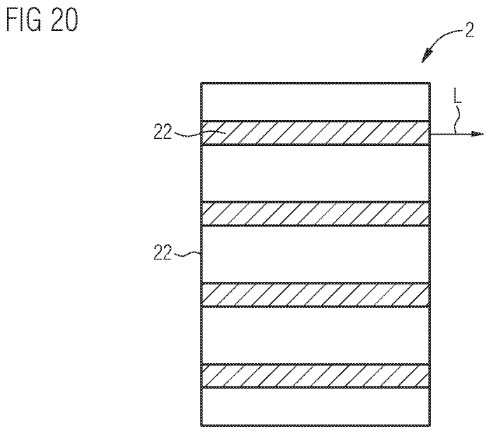

FIG. 20 schematically shows an exemplary embodiment of a laser bar 2 comprising several of the individual lasers 22. For example, only four of the individual lasers 22 are shown, but preferably the laser bar 2 comprises considerably more than four individual lasers 22, for example at least ten individual lasers 22.

The individual lasers 22 are structured, for example, as ridge waveguides, also referred to as ridges, from a semiconductor layer sequence 20. A fill factor of a laser-generating area, relative to a total area of the semiconductor layer sequence 20, is relatively small when viewed from above and is about 10%. The semiconductor layer sequence 20 is based on InGaN. An emission of the laser radiation L is parallel to the respective ridge waveguides in a direction perpendicular to a facet and perpendicular to a growth direction of the semiconductor layer sequence 20.

Unless otherwise indicated, the components shown in the figures preferably follow each other directly in the order indicated. Layers not touching each other in the figures are preferably spaced apart. Insofar as lines are drawn parallel to each other, the corresponding surfaces are preferably also aligned parallel to each other. Likewise, unless otherwise indicated, the relative positions of the drawn components to each other are correctly reproduced in the figures.

The invention described herein is not limited by the description based on the exemplary embodiments. Rather, the invention encompasses any new feature as well as any combination of features, which in particular includes any combination of features in the patent claims, even if that feature or combination itself is not explicitly specified in the patent claims or exemplary embodiments.

1. A semiconductor laser comprising:
a carrier;
a plurality of laser bars each comprising at least three individual lasers arranged parallel to one another; and
a plurality of deflection optics which are arranged downstream of the individual lasers of the laser bar,
wherein the laser bars and the deflection optics are mounted on the carrier and comprise a distance from each other of at most 4 mm,
wherein the laser bars are located at least on two opposite sides of the deflection optic,
wherein the laser bars associated to one deflection optic are arranged symmetrically with respect to the associated deflection optic,
wherein the deflection optics and the laser bars are arranged along several straight lines on a base surface of the carrier, such that at least one of the straight lines comprises once or more than once the following sequence: laser bar-deflection optic-laser bar-laser bar-deflection optic-laser bar, and
wherein said deflection optics are followed by a plurality of cylindrical lenses.

2. The semiconductor laser according to claim 1,
wherein the laser bars comprise a semiconductor layer sequence, wherein a fill factor is between 5% and 20% inclusive, and the fill factor is a quotient of a laser active area and a total area of the semiconductor layer sequence,
wherein the laser bars (2) are each configured to generate blue laser radiation (L) with a maximum intensity wavelength between 390 nm and 475 nm inclusive, and are based on the AlInGaN material system.

3. (canceled)

4. (canceled)

5. The semiconductor laser according to claim 1,
wherein the carrier comprises at least one stage,
wherein the laser bars are arranged in a plurality of planes parallel to a base surface of the carrier on the at least one stage, such that the laser bars of different planes comprise different distances from the associated deflection optic.

6. The semiconductor laser according to claim 1,
wherein the laser bars associated to one deflection optic are located in multiple planes on the carrier and on two opposite sides of the associated deflection optic,
wherein a distance between laser bars within a certain plane located on both sides of the associated deflection optic decreases from plane to plane along a main emission direction of the deflection optic.

7. (canceled)

8. (canceled)

9. The semiconductor laser according to claim 1,
wherein the at least one deflection optic, as seen in cross-section, comprises a triangular basic shape or is shaped as a symmetrical trapezoid, so that the deflection optic as a whole is a prism, a pyramid or a truncated pyramid.

10. The semiconductor laser according to claim 1,
further comprising at least one fast axis collimating lens optically located immediately downstream of the at least one laser bar, such that the collimating lens is located between the associated laser bar and the associated deflection optic.

11. The semiconductor laser according to claim 10,
wherein the at least one collimating lens is directly attached to the associated laser bar.

12. The semiconductor laser according to claim 1,
wherein the at least one deflection optic optically directly follows the at least one associated laser bar,
wherein the at least one deflection optic is configured for beam collimation.

13. The semiconductor laser according to claim 1,
wherein the carrier is formed as a housing or is integrated in a housing,
wherein at least one optical waveguide is attached to the housing, into which the laser radiation generated during operation is coupled.

14. The semiconductor laser according to claim 13,
further comprising at least one luminescent substance,
wherein the luminescent substance is configured for wavelength conversion of at least a portion of the laser radiation generated in operation, and
wherein the luminescent substance is located on and/or in the optical waveguide.

15. The semiconductor laser according to claim 1,
wherein the at least one laser bar is electrically contacted without bonding wires,
wherein at least one electrical lead is guided through the carrier.

16. The semiconductor laser according to claim 1,
wherein the carrier comprises a plurality of cooling channels configured to have a cooling liquid flowing therethrough.

17. The semiconductor laser according to claim 1,
which is configured for an optical output power of at least 0.4 kW.

18. A material processing method using a semiconductor laser according to at least claim 2,
wherein copper or a copper alloy is cut and/or welded by means of the blue laser radiation generated during operation.

19. A semiconductor laser comprising:
a carrier;
a plurality of laser bars each comprising at least three individual lasers arranged parallel to one another; and
a deflection optic which is arranged downstream of all individual lasers of all laser bars in common,
wherein the laser bars and the deflection optic are mounted on the carrier and comprise a distance from each other of at most 4 mm,
wherein the laser bars are located in multiple planes on the carrier and on two opposite sides of the deflection optic, and
wherein a distance between laser bars within a certain plane located on both sides of the associated deflection optic decreases from plane to plane along a main emission direction of the deflection optic.

20. The semiconductor laser according to claim 19,
wherein the laser bars are located at least on two opposite sides of the deflection optic,
wherein the laser bars are arranged symmetrically with respect to the deflection optic.

21. The semiconductor laser according to claim 19,
wherein the carrier comprises at least one stage, and
wherein the laser bars are arranged in a plurality of planes parallel to a base surface of the carrier on the at least one stage, such that the laser bars of different planes comprise different distances from the deflection optic.
